(19) United States
(12) Patent Application Publication
(10) Pub. No.: US 2025/0259818 A1
(43) Pub. Date: Aug. 14, 2025

(54) SYSTEM AND METHOD FOR SURFACE TREATMENT OF MATERIALS

(71) Applicants: CENTRE NATIONAL DE LA RECHERCHE SCIENTIFIQUE, PARIS (FR); UNIVERSITE D'ORLEANS, ORLEANS (FR)

(72) Inventors: Eric ROBERT, ORLEANS (FR); Jean-Michel POUVESLE, SAINT-PRYVE-SAINT-MESMIN (FR); Sébastien DOZIAS, SAINT JEAN DE LA RUELLE (FR); Pablo ESCOT BOCANEGRA, OLIVET (FR); Augusto STANCAMPIANO, ORELANS (FR)

(73) Assignees: CENTRE NATIONAL DE LA RECHERCHE SCIENTIFIQUE, PARIS (FR); UNIVERSITE D'ORLEANS, ORLEANS (FR)

(21) Appl. No.: 18/855,005

(22) PCT Filed: Apr. 6, 2023
(86) PCT No.: PCT/EP2023/059216

§ 371 Date: Nov. 14, 2024

(30) Foreign Application Priority Data
Apr. 8, 2022 (FR) 2203229

(51) Int. Cl. H01J 37/30; H01J 37/20

(52) U.S. Cl. CPC H01J 37/30; H01J 37/20; H01J 2237/30

(57) ABSTRACT

A system for surface treatment of materials, including a target material, at least one transfer device and at least one plasma generator device. The plasma generator device includes a fluid (formula B) and generates a column of cold plasma. The target material is able to travel a path between a starting point and an end point, passing through the plasma generator device and the plasma column, along a unit vector of movement. The transfer device includes a fluid (formula A) transferred from the transfer device to the plasma generator device. The plasma column, generated from the fluids (formula A) and (formula B), has an oblong geometric shape of length (formula C), according to a longitudinal axis colinear with the vector of movement, and of width (formula D), according to a transverse axis perpendicular to the vector of movement, such that (formula E).

### TECHNICAL FIELD

The present invention relates generally to materials, and in particular to a system and a method for surface treatment of materials using plasma generator devices.

Systems for surface treatment of materials are typically used in a wide range of fields such as biomedical, cosmetics, material treatment by surface functionalization, lighting, etc.

Known systems for surface treatment of materials use chemical products, either by passing objects through baths or by spraying/evaporation techniques in order to carry out the surface treatment of materials. However, such solutions require the external supply of chemical components, and are therefore not environmentally friendly.

To avoid the use and storage of chemicals, other systems for surface treatment of materials use so-called “plasma” techniques to treat materials. These plasma techniques can be implemented using “torches” or even DBD (for “dielectric barrier discharges”) systems.

However, known plasma techniques are limited in the gas mixtures for plasma generation. In fact, they do not allow materials to be treated with high concentrations of additional gases (such as for example high percentages of nitrogen or oxygen in noble gases), leading to plasma quenching.

Furthermore, some known techniques (such as torches) consume considerable power. In addition, in the case of torches, the technique is unsuitable for heat-sensitive materials and poorly suited to treating moving objects. In DBD systems, they can lead to inhomogeneous treatments, as plasmas are difficult to produce homogeneously at atmospheric pressure. Thus, these techniques cannot guarantee direct and homogeneous treatment in the case of substantially cylindrically symmetrical objects with very high aspect ratios, such as fibers or wires, ribbons, tubes or capillaries. In addition, these techniques cannot guarantee fast and efficient treatment of these materials and these objects either, due to the small volume of plasma generated at atmospheric pressure.

There is thus a need for an improved surface treatment method and system capable of treating the surface of materials without degradation, at atmospheric pressure, and in a manner suitable for hollow materials such as tubes or capillaries.

### SUMMARY

The present invention improves the situation by proposing a system for surface treatment of materials comprising a target material, at least one transfer device at least one plasma generator device, the transfer device comprising a fluid [symbol] to be transferred to the plasma generator device, the plasma generator device comprising a fluid [symbol] and being configured to generate a column of cold plasma, the target material being able to travel a path, between a starting point and an end point, the path passing through at least the plasma generator device and the plasma column, the path being defined in a given reference frame along a unit vector of movement \vec{t}, the fluid [symbol] being transferred from the transfer device to the plasma generator device, and the plasma column being generated from the fluid [symbol] and the fluid [symbol] . The plasma column has an oblong geometric shape defined by a length [symbol] , a width [symbol] and an aspect ratio

$$\frac{ℒ}{ℓ} \geq 1 ,$$

the length [symbol] being defined along a longitudinal axis colinear with the vector of movement \vec{t} and the width [symbol] being defined according to a transverse axis perpendicular to the vector of movement \vec{t}.

In one embodiment, the target material can further pass through at least part of the transfer device.

The plasma generator device may comprise a capillary for generating a plasma column comprising an inlet port configured to receive target material at the capillary inlet and an outlet port configured to deliver the target material at the capillary outlet.

In embodiments, the plasma generator device is a T-shaped device, further comprising a module for controlling and supplying fluid [symbol] and a guide for transporting fluid [symbol] , the control and supply module being configured to apply a pulsed discharge in the fluid [symbol] at a discharge frequency f₂. The guide and capillary of the T-shaped device can each have a shape and dimensions selected based on the target material and on the surface treatment to be applied.

In some embodiments, the transfer device may be a T-shaped device configured to generate a plasma column, the transfer device and the plasma generator device being spaced apart by a distance ε₁₋₂ representing the distance between the inlet port of the plasma generator device and the outlet port of the transfer device. The plasma column can be generated based on the distance ε₁₋₂.

In particular, the capillary of the plasma generator device may comprise at least one part made of a conductive material and at least one part made of a dielectric material.

The target material may further have a width ϕ and the capillary may have a width [symbol] . The transfer device may be an enclosure attached to the plasma generator device, and connected at the inlet port of the plasma generator device by a connection having a given shape and an opening of diameter δ such that ϕ<δ≤ [symbol] . The connection may allow the transfer of fluid [symbol] into the capillary and the plasma column may be generated based on the connection.

The target material may be a fiber, a wire or a capillary, wound, at the starting point, into a starting coil, and at the end point into an end coil, each coil being able to be unwound and wound so that the target material travels the path at a given speed defined based on the surface treatment to be applied.

The invention also provides a method of manufacturing an object from at least one system for surface treatment of materials comprising at least one target material, at least one transfer device and at least one plasma generator device, the target material traveling a path between a starting point and an end point along a unit vector of movement \vec{t}, the transfer device comprising a fluid [symbol] , the plasma generator device comprising a fluid [symbol] , the method comprising the steps of:
transferring the fluid [symbol] from the transfer device to the plasma generator device,
generating a cold plasma column at surrounding pressure by means of the plasma generator device from fluids [symbol] and [symbol] , the plasma column having an oblong geometric shape defined by a length [symbol] , a width [symbol] and an aspect ratio noted

$$\frac{ℒ}{ℓ} \geq 1 ,$$

the length [symbol] being defined according to a longitudinal axis colinear with the vector of movement \vec{t} and the width [symbol] is defined according to a transverse axis perpendicular to the vector of movement \vec{t}, and
passing the target material along the path, through the plasma generator device, at least when the plasma column is generated.

The method further comprises a step of passing the target material through the transfer device.

The method and system for surface treatment of materials according to the embodiments of the invention allow multiple atmospheric plasmas to be generated, involving gas mixtures that are impossible to obtain from prior art plasma reactors. These plasmas can be generated over long lengths and are suitable for inhomogeneous and/or homogeneous treatment of materials with very high aspect ratios. These plasmas can further be generated by interchangeable devices in a system with low energy consumption.

### BRIEF DESCRIPTION OF FIGURES

Further features, details and advantages of the invention will become apparent upon reading the description made with reference to the appended drawings given by way of example.

FIG. 1 is a diagram showing a system for surface treatment of materials, according to embodiments of the invention.

FIG. 2 is a diagram showing a plasma generator device, according to an example of use of the invention.

FIG. 3 is a diagram showing a plasma generator device, according to another example of use.

FIG. 4 is a diagram showing a transfer device and a plasma generator device arranged in series, according to embodiments of the invention.

FIG. 5 is a diagram showing a transfer device and a plasma generator device arranged in series and connected by a connection port, according to other embodiments of the invention.

FIG. 6 is a diagram showing a transfer device and a plasma generator device arranged in series and connected by a connection nozzle, according to other embodiments of the invention.

FIG. 7 is a diagram showing a controlled mixing zone between a transfer device and a plasma generator device arranged in series and connected by a connection port, according to other embodiments of the invention.

FIG. 8 is a diagram showing a transfer device and two plasma generator devices arranged in series, according to embodiments of the invention.

FIG. 9 is a diagram showing a device for treating materials in the presence of liquid or gel, according to embodiments of the invention.

FIG. 10 is a diagram showing a system for surface treatment of materials, according to embodiments of the invention.

FIG. 11 is a flowchart showing a method for manufacturing an object from the system for surface treatment of materials, according to embodiments of the invention.

Identical references are used in the figures to designate identical or similar elements. For reasons of clarity, the elements shown are not to scale.

### DETAILED DESCRIPTION

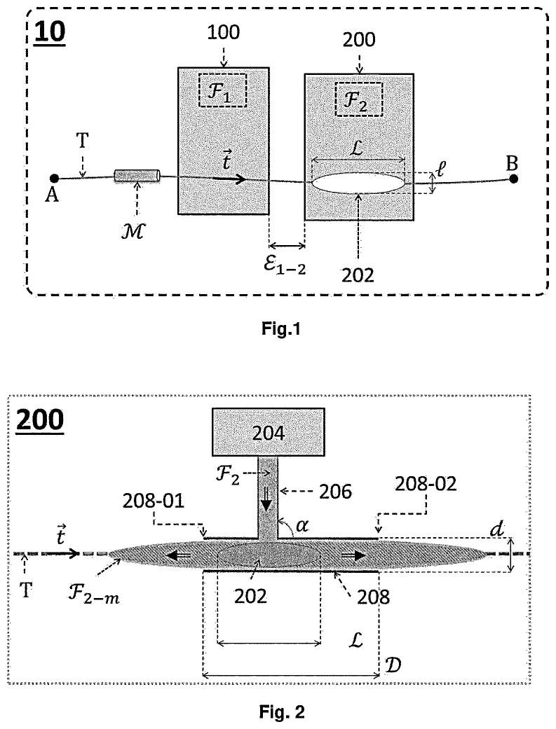

FIG. 1 schematically shows a system for surface treatment of materials 10 comprising a target material [symbol] , a transfer device 100 and a plasma generator device 200.

The surface treatment system, according to the embodiments of the invention can be used in various fields of application, such as, for example and without limitation, the field of biomedicine, sterilization, medicine, cosmetics, material treatment by surface functionalization, ultrafine pattern production, depollution and/or decontamination, germination, lighting, rapid switching, flow modification, detection, metrology, etc.

The target material [symbol] may be composed of one or more inert dielectric or conductive materials and/or biological tissue. The target material [symbol] comprises a surface that can be defined, for example, by its chemical and/or structural composition, and/or its surface finish. The surface of a material is defined in particular by specific surface properties such as for example physical properties, optical properties, and/or electrical properties, etc.

Some of these surface properties can be modified during and/or after interaction of the target material [symbol] with a plasma at ambient temperature or very close to ambient temperature.

As used herein, the term “plasma” refers to a cold plasma formed at ambient pressure defined by a gaseous plasma (made up of charged species and electrons) out of thermodynamic equilibrium, in which the temperature of the electrons is very high compared to the temperature of the other species contained in the plasma. The temperature of the other species remains close to ambient temperature.

A plasma formed by the devices of the system for surface treatment of materials 10 generates a controlled and homogeneous production of reactive species. These species are excited chemical elements or elements in their ground state (for example NO, OH, NO₂, H₂O₂, O, O₃, etc.) with given life spans. In particular, some species have so-called ‘short’ life spans defined such that these reactive species are contained in the formed plasma, while other species have so-called ‘long’ life spans defined such that these other reactive species can be moved out of the formed plasma.

For example, and in a non-limiting way, the interaction of the target material [symbol] with a plasma can modify the wettability of the surface of the target material [symbol] by any type of physical or chemical process notably including but not limited to abrasion (or degreasing), deposition, functionalization, grafting or even cross-linking. In another example, the interaction of the target material [symbol] with a plasma containing nanoparticles can modify the optical refraction or fluorescence of the surface of the target material [symbol] by depositing thin layers.

In particular, the interaction of the target material [symbol] with a plasma can locally induce a production of reactive species on the surface, used for example to decontaminate the target material [symbol] .

The target material [symbol] may be an object with a large aspect ratio or cylindrical symmetry, defined according to a diameter noted Φ. The target material [symbol] may be for example a fiber, a wire, a tube or a capillary. The diameter Φ of such a target material [symbol] may be characterized by a maximum value Φₘₐₓ, that is, that the diameter Φ is less than the maximum diameter value Φₘₐₓ. The maximum value Φₘₐₓ may be as little as a few millimeters. For example and without limitation, the maximum value Φₘₐₓ may be 8 mm (Φ<8 mm).

Advantageously, the target material [symbol] treated by the system for surface treatment of materials 10 may be used to manufacture multi-composite woven objects. Such objects are for example used in a biomedical or cosmetic field of application of the invention.

The system for surface treatment of materials 10 is associated with a given reference frame, noted [symbol] . The target material [symbol] is able to travel a path T, defined along a unit vector of movement \vec{t} between a starting point A and an end point B, in the reference frame [symbol] . The path T passes through at least the plasma generator device 200.

In some embodiments, the path T may further pass partially or completely through the transfer device 100. In other embodiments, the path T does not pass through the transfer device 100.

In embodiments where the path T passes at least partly through the transfer device 100, the transfer device 100 and the plasma generator device 200 are arranged “in series” in the system for surface treatment of materials 10. In such an embodiment, the path T may therefore extend between a starting point A, located upstream (or inside) of the transfer device 100 and an end point B, located downstream of the plasma generator device 200, in the reference frame [symbol] , as shown in FIG. 1.

In some embodiments, all or part of the system for surface treatment of materials 10 may be enclosed in a chamber (also known as an “enclosure”) configured to control environmental parameters such as pressure, temperature and humidity, but also the quality of the air in the chamber or even the composition of the surrounding gas. For example, and without limitation, the pressure in the chamber can be set between 0.5 atm and 5 atm (the unit atm corresponds to normal atmospheric pressure), the temperature can be set between 0° C. and 50° C., and the humidity between 0% and 100%.

The transfer device 100 and the plasma generator device 200 are separated from each other by a distance of ε₁₋₂. The distance ε₁₋₂ can be positive, negative or zero. This distance is defined based on the target material [symbol] of the surface treatment, and on the embodiment used to implement the devices 100 and 200.

The transfer device 100 comprises a fluid [symbol] and the plasma generator device 200 comprises a fluid [symbol] . These fluids move in their respective devices according to characteristic parameters (such as for example the flow rate or the direction of fluid flow). In some embodiments, the fluids [symbol] and [symbol] may be identical. Alternatively, the fluids [symbol] and [symbol] may be different and/or have one or more different characteristic parameters.

Each fluid [symbol] and [symbol] may be a gas or a mixture of gases in which and/or from which a plasma can be formed.

For example, each of the fluids [symbol] and/or [symbol] may be air, nitrogen, oxygen, etc. Alternatively, each fluid [symbol] and/or [symbol] may be a mixture of gases. In embodiments where all or part of the system for surface treatment of materials 10 is enclosed in a chamber, fluid [symbol] or fluid [symbol] can be defined by the composition of the surrounding (or ambient) gas which depends on various chamber control parameters.

In some embodiments, each fluid [symbol] and/or [symbol] may be a noble gas, or a mixture of noble gases (typically helium He, argon Ar, neon Ne etc.).

The gases (and/or noble gases) used may further comprise one or more minority constituents, that is, added in low concentration. These constituents may be molecular gases corresponding, for example, to oxygen O₂, hydrogen H₂, sulfur hexafluoride SF₆, nitrogen N₂ and/or to any type of gas resulting from the vaporization of a liquid, such as water vapor H₂O. In particular, a molecular gas may or may not be loaded with nanoparticles (of a metallic or dielectric nature, etc.), or with any type of precursor such as molecular polymer precursors.

The plasma generator device 200 may be configured to generate a column 202 of cold plasma formed at ambient pressure from fluid [symbol] and fluid [symbol] transferred from the transfer device 100 to the plasma generator device 200. This plasma column 202 has a substantially oblong geometric shape, defined by a length [symbol] and a width [symbol] . As used herein, the term “width [symbol] ” refers to the diameter of the plasma column 202 at the center thereof as shown in FIG. 1. The geometric shape is defined by a ratio [symbol] , also known as the “aspect ratio”. As the geometric shape is oblong, the value of the length [symbol] of the plasma column 202 is greater than the value of the width [symbol] . The aspect ratio of the plasma column 202 is therefore defined by equation (1):

$$\frac{ℒ}{ℓ} \geq 1 \qquad ( 1 )$$

Advantageously, the length [symbol] of the plasma column 202 is defined according to a longitudinal axis colinear with the vector of movement \vec{t} and the width [symbol] is defined according to a transverse axis perpendicular to the vector of movement \vec{t}.

In this way, the target material [symbol] passes through the plasma column 202, longitudinally and along path T. One or more surface properties of the target material [symbol] are then modified by the interaction between the target material [symbol] and the plasma column 202.

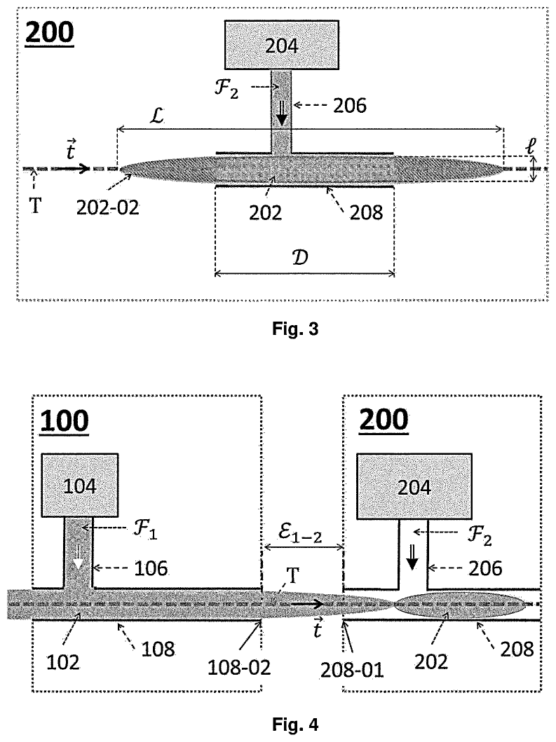

FIGS. 2 and 3 show a plasma generator device 200, according to different embodiments and examples of use of the invention. The plasma generator 200 is configured to generate a plasma column 202 from one or more fluids.

The plasma generator device 200 may comprise a module 204 for controlling and supplying fluid [symbol] , a guide 206 for transporting fluid [symbol] and a capillary 208 for generating the plasma column 202.

The module 204 for controlling and supplying fluid [symbol] may comprise a supply enclosure connected to the source of fluid [symbol] , and configured to supply fluid [symbol] to the capillary 208 through the guide 206. The supply of fluid [symbol] is then controlled, by the module 204, according to characteristic parameters such as flow parameters associated with:
the flow rate of fluid [symbol] in the guide 206 and/or the capillary 208, noted ρ₂, or even,
the flow modulation m₂ of fluid [symbol] , which generates a flow that can be continuous or discontinuous (or intermittent).

For example, fluid [symbol] can flow through guide 206 at a flow rate ρ₂ between 0.001 l/mn and 10 l/mn.

In embodiments, the control and supply module 204 may be a device for producing a “plasma jet” obtained from a plasma-forming gas, as described for example and without limitation in WO 2009/050240 and WO 2016/083539.

In one embodiment, a “plasma jet” production device may comprise a supply enclosure connected to a source of fluid [symbol] in which are housed one or two electrodes connected to a high-voltage generator (elements not shown in the figures). Reference is made to the notion of a plasma “jet” as the plasma propagates beyond the discharge electrodes through the flow of fluid [symbol] . In these embodiments, the control and supply module 204 can control another characteristic parameter corresponding to the discharge parameter (also known as “pulsed discharge”). A pulsed discharge is a discontinuous discharge of plasma jet into fluid [symbol] and is defined by a discharge frequency f₂.

For example, the pulsed discharge in fluid [symbol] can be defined so as to obtain a cold plasma in the plasma column 202, the discharge frequency f₂ being selected according to the target material [symbol] and the surface treatment.

The shapes, dimensions and constituent materials of the guide 206 for transporting fluid [symbol] and the capillary 208 for generating the plasma column 202 may advantageously depend on the type of target material [symbol] and/or on the surface properties of the target material [symbol] to be modified.

The guide 206 and/or capillary 208 may be made of one or more rigid or flexible materials, from dielectric materials or conductive materials coated with no, one or more dielectric materials. The plasma column 202 forms in the capillary 208 at the level of dielectric materials (or conductive materials whose interior of the capillary is coated with dielectric materials).

The guide 206 and/or the capillary 208 may be cylindrical in shape. The guide 206 may further extend transversely to the direction of the vector of movement \vec{t}, at any angle α. In such embodiments, the plasma generator device 200 is referred to as a T-shaped device. For example and without limitation, the angle α may be substantially equal to 90° so that the orientation of the guide 206 may be perpendicular to that of the capillary 208. In this way, the target material [symbol] traveling path T passes longitudinally through the capillary 208 and the plasma column 202 generated.

The capillary 208 for generating the plasma column 202 may comprise an inlet port 208-01 configured to receive the target material [symbol] and an outlet port 208-02 for delivering the target material [symbol] out of the capillary 208, the inlet and outlet ports 208-01 and 208-02 being positioned on path T.

As shown in FIGS. 2 and 3, the capillary 208 can be defined by its diameter [symbol] and its length [symbol] . For example, the diameter [symbol] of the capillary 208 can be between 500 μm and 1 cm. In particular, the diameter [symbol] of the capillary 208 can be defined in relation to diameter Φ of the target material [symbol] , such that d>Φ, taking into account certain stresses such as for example the mechanical stresses of movement of the target material [symbol] passing longitudinally through the capillary 208. Advantageously, diameter [symbol] of the capillary 208 may be slightly greater than diameter Φ of the target material [symbol] such that [symbol] ≥Φ, which allows a plasma column 202 to be generated at a lower energy cost.

In addition, the guide 206 may or may not be positioned in the middle of the capillary 208 of length [symbol] . If the guide 206 is positioned in the middle of the capillary, the T-shaped device may be symmetrical. Otherwise, the T-shaped device is asymmetrical. For example, an asymmetrical T-shaped device may comprise a capillary 208 defined by two legs, referred to respectively as a ‘long leg’ of length [symbol] _{long} and ‘short leg’ of length [symbol] _{court} such that [symbol] _{long}> [symbol] _{court} and that [symbol] = [symbol] _{long}+ [symbol] _{court}. Alternatively, an asymmetrical T-shaped device may comprise a capillary 208 comprising two legs defined with respect to the position of the guide 206, and having respectively a large diameter [symbol] _{grand} and a small diameter [symbol] ₚₑₜᵢₜ, such that [symbol] _{grand}> [symbol] ₚₑₜᵢₜ.

The guide 206 may also be defined by its diameter [symbol] _{g} and its length [symbol] _{g}. In particular, diameter [symbol] _{g} of the guide 206 may be defined in relation to diameter [symbol] of the capillary 208.

More generally, parameters [symbol] , [symbol] , [symbol] _{g} and [symbol] _{g} are related to flow parameters of fluid [symbol] , the nature of fluid [symbol] or even to the pulsed discharge in fluid [symbol] . These parameters can influence the characteristic parameters for formation of the plasma column 202, such as for example its diameter [symbol] and its length [symbol] .

For example, the evolution of fluid [symbol] in the device can be characterized in particular by the flow parameter and the flow velocity of fluid [symbol] in the capillary 208 may depend on a condition relating to diameter [symbol] _{g} of the guide 206 and to diameter [symbol] of the capillary 208. In particular:
if diameter [symbol] _{g} of the guide 206 is greater than or equal to diameter [symbol] of the capillary 208 ( [symbol] _{g}≥ [symbol] ), fluid [symbol] flowing from the guide 206 to the capillary 208 undergoes an increase in flow velocity in the capillary 208, relative to the guide 206, and
alternatively, if diameter [symbol] _{g} of the guide 206 is strictly less than diameter [symbol] of the capillary 208 ( [symbol] _{g}< [symbol] ), fluid [symbol] undergoes a reduction in flow velocity in the capillary 208, relative to the guide 206.

In some embodiments, diameter [symbol] of the plasma column 202 may be such that [symbol] ≥Φ in order to obtain a certain efficiency and homogeneity of surface treatment of the target material [symbol] .

For example, length [symbol] of the plasma column 202 may be between 1 cm and 100 cm.

Length [symbol] of the plasma column 202 may further depend on the nature of fluid [symbol] . For example, and without limitation, a pure gas may generate a longer length [symbol] ₚᵤᵣₑ of the plasma column 202 than a gas mixture generating a length [symbol] ₘᵢₓₜₑ of the plasma column 202, such that [symbol] ₚᵤᵣₑ> [symbol] ₘᵢₓₜₑ. Fluid [symbol] flowing through the capillary 208 to inlet and outlet ports 208-01 and 208-02 mixes with the surrounding air (or ambient air or surrounding gas or even gas in the chamber) outside or inside the capillary 208. Thus, the flow parameters of fluid [symbol] can similarly influence the length [symbol] of the plasma column 202. The high flow velocity (or high flow rate) may limit the mixing of fluid [symbol] with the surrounding air and therefore influence certain characteristics of the plasma column 202 generated. For example, a device 200 using a high flow velocity in the capillary 208 may generate a longer length [symbol] _{forte} of the plasma column 202 than a device 200 using a low flow velocity in the capillary 208 generating a length [symbol] _{faible} of the plasma column 202, such that [symbol] _{forte}> [symbol] _{faible}.

By way of illustrative example, FIG. 2 shows a device comprising a plasma column 202 held in the capillary 208, such that [symbol] < [symbol] . FIG. 3 shows a device alternatively comprising a plasma column 202 extending on either side of the inlet and outlet ports 208-01 and 208-02 of capillary 208, such that [symbol] > [symbol] .

In the operating mode shown in FIG. 2, fluid [symbol] flows from the control and supply module 204, through the guide 206, then through the plasma column 202 according to flow parameters defined for example by the velocity of fluid [symbol] to the inlet and outlet ports 208-01 and 208-02. In particular, the plasma column 202 may comprise reactive species with ‘long life spans’ that can be carried away/displaced from the plasma formed depending on the direction of flow of the fluid. The result is a modified fluid [symbol] , referred to as fluid [symbol] comprising reactive species. The length of this modified fluid [symbol] depends in particular on the life span of the species and on the flow rate of fluid [symbol] . Advantageously, the smaller the diameters involved, the greater the speeds at which the species can move and the greater the distances fluid [symbol] and the reactive species can travel.

The operating mode shown in FIG. 3 shows a propagation zone of the plasma column 202 outside the capillary 208, also known as the “plasma plume” 202-02. The plasma plume 202-02 corresponds to the plasma column 202 interacting outside the capillary 208 with ambient air for example. The so-called plasma properties of the plasma plume 202-02 and the plasma column 202 may therefore be different.

The external supply of fluid [symbol] can be provided by the transfer device 100. For example and in a non-limiting way, the supply of fluid [symbol] can be achieved by means of:
another plasma generator device as described in relation to FIGS. 2 and 3; or
an enclosure connected to a plasma-forming gas source.

FIG. 4 shows the transfer device 100 and the plasma generator device 200 arranged in series, according to the embodiment of the invention wherein the external supply of fluid [symbol] is provided by another plasma generator device (as described in relation to FIGS. 2 and 3).

In such an embodiment, the transfer device 100 may comprise the same characteristics as the plasma generator device 200 described in relation to FIGS. 2 and 3. Thus, the transfer device 100 may be configured to generate a plasma column 102 from one or more fluids. The transfer device 100 may also comprise a control and supply module 104 for fluid [symbol] , a guide 106 for transporting fluid [symbol] and a capillary 108 for generating the plasma column 102, also of oblong geometric shape. The transfer device 100 may be a T-shaped device such that the orientation of the guide 106 may extend substantially perpendicular to the orientation of the capillary 108.

As shown in FIG. 4, in some embodiments, the target material [symbol] traveling path T can pass longitudinally and completely through capillary 108 and the generated plasma column 102.

Alternatively, in other embodiments (not shown in the figures), the target material [symbol] may not pass through the transfer device 100. In such an embodiment, the capillary 108 and the generated plasma column 102 may for example have a transverse direction or at a given angle to the longitudinal direction of path T.

The devices 100 and 200 may be identical and induce identical fluids [symbol] and [symbol] . Alternatively, fluids [symbol] and [symbol] may be different and/or the devices 100 and 200 may be different or comprise one or more different characteristic parameters associated with the control and supply of fluids. For example, the flow rates of fluids [symbol] and [symbol] in the capillaries 108 and 208 may be equal or different and/or defined according to different, identical synchronous or asynchronous flow modulations of fluids m₁ and m₂. Similarly, pulsed discharges from modules 104 and 204 in fluids [symbol] and [symbol] may be defined by different, identical synchronous or asynchronous discharge frequencies and/or discharge frequency modulations f₁ and f₂.

In the embodiment s own in FIG. 4, the capillary 108 comprises an inlet port 108-01 configured to receive the target material [symbol] and an outlet port 108-02 configured to deliver the target material [symbol] out of the capillary 108. The inlet and outlet ports may therefore be positioned on path T. In this case, the target material [symbol] passes through the transfer device 100 and the plasma generator device 200 arranged in series, and the target material [symbol] passes through the plasma column 102 and the plasma column 202, longitudinally, along path T. Thus, one or more surface properties of the target material [symbol] may be modified by the interaction between the target material [symbol] and the plasma columns 102 and 202.

Distance ε₁₋₂ between the transfer device 100 and the plasma generator device 200, shown in FIG. 4, corresponds to the distance between the outlet port 108-02 of the transfer device 100 and the inlet port 208-01 of the plasma generator device 200. In other embodiments, the order of the devices may be reversed on path T, so that distance ε₁₋₂ represents the distance between the outlet port 208-02 of the plasma generator device 200 and the inlet port 108-01 of the transfer device 100.

In these embodiments, distance ε₁₋₂ between the capillaries can be selected based on the type of target material [symbol] and the surface treatment to be applied. In particular, the variability of the spacing ε₁₋₂ between capillaries 108 and 208 can influence the interaction between devices 100 and 200, so that the plasma generator device 200 can generate a plasma column 202 from fluid [symbol] and fluid [symbol] .

To this end, in the example shown in FIG. 4, the transfer device 100 may be configured to generate a plasma column 102 of length [symbol] > [symbol] , so that a plasma plume 102-02 exits from the outlet port 108-02. Fluid [symbol] then comprises a plasma jet generating a plasma column 102. The spacing ε₁₋₂ thus influences the interaction (or mixing) of the plasma plume 102-02 with:
a plasma plume 202-02,
the plasma column 202,
fluid [symbol] containing reactive species, and/or
fluid [symbol] .

In particular, the plasma plume 102-02 can reach fluid [symbol] discharged into the capillary 208 (at any angle defined by path T) and thus generate a plasma column 202 by plasma transfer, from a new fluid resulting from mixing fluids [symbol] and [symbol] . In this zone of interaction (or transfer), it should be noted that the spacing ε₁₋₂ can also influence the treatment of the material [symbol] locally.

The spacing ε₁₋₂ may notably be negative, zero or positive. Negative spacing ε₁₋₂ corresponds notably to the case where one of the two capillaries 108 or 208 is inserted into the other capillary, depending on the respective diameters thereof. In addition, positive spacing ε₁₋₂ may be less than a maximum distance noted ε₁₋₂^{max} (with for example and without limitation: ε₁₋₂^{max}==10 cm) corresponding to the upper limit of interaction possible between the plasmas and/or fluids of the two devices 100 and 200.

In embodiments using an asymmetrical T-shaped device the capillary 208 of the plasma generator device 200 may comprise two legs of different diameters [symbol] _{grand} and [symbol] ₚₑₜᵢₜ. Advantageously, the leg of capillary 208 having diameter [symbol] _{grand} may comprise the inlet port 208-01 positioned at a distance ε₁₋₂ from the outlet port 108-02 of the device 100 and the leg of the capillary 208 having diameter [symbol] ₚₑₜᵢₜ may comprise the outlet port 208-02 of the material [symbol] so that diameter [symbol] ₚₑₜᵢₜ is defined to best match diameter Φ. Such an asymmetrical T-shaped device minimizes flow transfer problems in the interaction zone between devices 100 and 200, while limiting the energy consumed to generate the plasma 202.

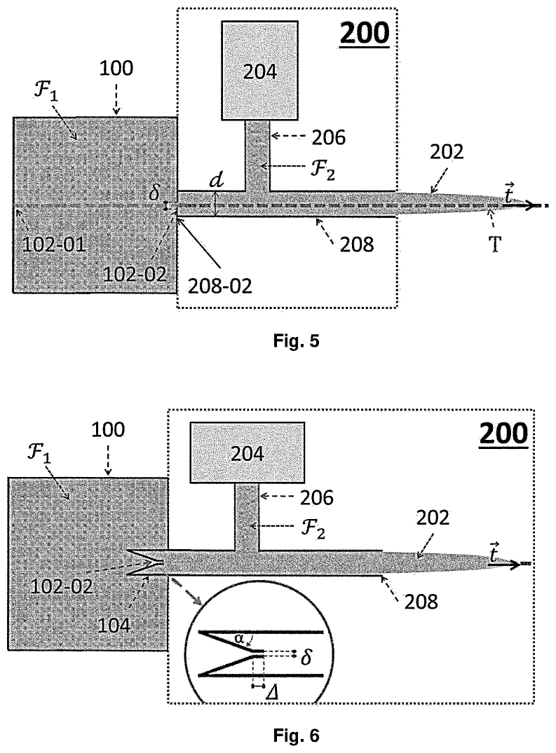

FIGS. 5 to 7 show embodiments of the invention in which the external supply of fluid [symbol] is provided by an enclosure connected to a source of plasma-forming gas.

In particular, FIG. 5 shows a series arrangement of the transfer device 100 and the plasma generator device 200, according to such embodiments of the invention.

The transfer device 100 may be composed of an enclosure (open or closed) comprising a fluid [symbol] (for example a plasma-forming gas, as described above) and/or a source of fluid [symbol] . The enclosure further comprises an outlet port 102-02 of the target material [symbol] positioned on path T. The source of fluid [symbol] can be configured to control the supply of fluid [symbol] according to characteristic parameters such as the flow rate of fluid [symbol] in the enclosure or through the outlet port 102-02.

The starting point A of path T of the target material [symbol] may be located inside the enclosure of the transfer device 100. Alternatively, the starting point A may be located outside the enclosure of the transfer device 100 so that path T of the target material [symbol] passes through the transfer device 100. The transfer device 100 may then also comprise an inlet port 102-01 of the target material [symbol] positioned on path T.

Distance ε₁₋₂ between the transfer device 100 and the plasma generator device 200 is positive, negative or zero. In some embodiments, as shown in FIG. 5, 6 or 7 for example, the transfer device 100 may thus be joined to the plasma generator device 200 via a connection coinciding with the outlet port 102-02 of the transfer device 100 and the inlet port 208-01 of the plasma generator device 200. The connection positioned on path T coinciding with the joining of devices 100 and 200 will be noted below [symbol] .

Connection [symbol] has a specific shape and an opening of diameter δ₁₋₂ through which fluid [symbol] is fed into the capillary 208 generating the plasma column 202. The minimum value δ₁₋₂^{min} of diameter δ₁₋₂ can be defined in relation to diameter Φ of the target material [symbol] , such that δ₁₋₂>ϕ. Similarly, the maximum value δ₁₋₂^{max} of diameter δ₁₋₂ can be defined in relation to diameter [symbol] of the capillary 208 generating the plasma column 202, such that δ₁₋₂≤ [symbol] .

As shown in FIG. 5, the connection [symbol] may comprise an injection port. For example, diameter δ₁₋₂ of the injection port may be between 500 μm and 5 mm. Such an injection port allows a simple supply of fluid [symbol] , and the diameter δ₁₋₂ influences the flow rate ρ₁ of the fluid. In some embodiments, the connection [symbol] may comprise a unit for controlling diameter δ₁₋₂ of the injection port to modify or modulate the flow of fluid [symbol] to the device 200. For example, this control unit may comprise a diaphragm or a slit system.

The embodiment shown in FIG. 6 is similar to that shown in FIG. 5 but features a connection [symbol] having a shape comprising a so-called “moving” surface, which may advantageously be structured, textured or porous. The specific shape of the connection [symbol] as shown in FIG. 6 may be, by way of example, a connection nozzle comprising an injection cone of angle α, and an injection port of length noted Δ, according to diameter δ₁₋₂. For example, angle α of the injection cone may be between 30° and 50°, and length Δ of the injection port may be between 1 mm and 20 mm.

Advantageously, the moving surface induces entrainment of fluid F₁ towards the capillary 208 of the plasma generator device 200 to induce generation of the plasma column 202. A connection [symbol] in the form of an injection nozzle further allows a more complex supply of fluid [symbol] , inducing for example, an acceleration of the velocity of fluid [symbol] and thus an increase in flow rate ρ₁ compared with a simple supply.

The transfer device 100 may further comprise one or more units for supplying one or more additional fluids to fluid [symbol] (units not shown in the figures). These additional fluids may be steam, mist of microdroplets and/or microparticles or nanoparticles or powders. For example, and without limitation, these additional fluids can be produced by evaporation, nebulization or smoke; an additional fluid supply unit can then be an evaporator, a nebulizer, etc. An additional fluid supply unit can be configured to inject an additional fluid and/or fluid [symbol] in a controlled manner at connection [symbol] .

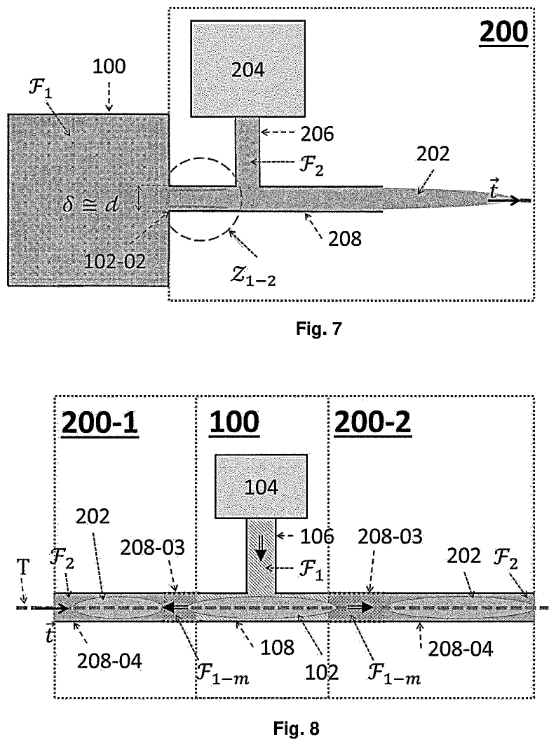

FIG. 7 shows a mixing zone [symbol] between a transfer device 100 and a plasma generator device 200 arranged in series, according to another embodiment of the invention. This mixing zone [symbol] is located at the start of capillary 208 generating the plasma column 202 on path T.

Advantageously, the control of the mixing of fluids [symbol] and [symbol] in zone [symbol] can be improved by using pulsed discharges from module 204 at a discharge frequency f₂ in fluid [symbol] . This discharge frequency f₂ in fluid [symbol] is such that it induces entrainment of fluid [symbol] according to a fluidodynamic (i.e. related to fluid dynamics) and electrodynamic process, which may depend on the flow rate ρ₂ of fluid [symbol] in the capillary 208. As shown in FIG. 7, the fluidodynamic and electrodynamic process may induce the flow of fluid [symbol] along the walls of capillary 208 in the mixing zone [symbol] .

In the non-limiting example shown in FIG. 7, the specific shape of connection [symbol] is a connection port such that δ₁₋₂= [symbol] .

In particular, the use of a device 100 and a device 200, arranged in series, allows pre-treatment of the target material [symbol] in device 100 prior to subsequent plasma treatment in device 200, resulting in more efficient surface treatment of the target material [symbol] .

FIG. 8 shows a transfer device 100 and two plasma generator devices 200-1 and 200-2 arranged in series, according to other embodiments of the invention.

In such embodiments, the transfer device 100 is a device similar to the plasma generator device described in relation to FIGS. 2 and 3. The transfer device 100 is thus designed as a device comprising a control and supply module 104, a guide 106 and a capillary 108. In particular, module 104 may be a plasma jet production device for generating a plasma column in capillary 108 from a fluid [symbol] .

In the example shown in FIG. 8, plasma generator devices 200-1 and 200-2 comprise capillaries 208 which are symmetrical relative to the transfer device 100 and positioned respectively at the inlet and outlet of capillary 108. The target material [symbol] traveling path T may pass through one or more of these capillaries 108 and/or 208.

The capillaries 208 comprise a fluid [symbol] , for example air. The capillaries 208 may consist of at least two parts 208-03 and 208-04 made of different materials. For example, as shown in FIG. 8, the inner surface of capillary 208 of part 208-03 may be made of a conductive material that does not allow the plasma column 102 to propagate through plasma generator devices 200-1 and 200-2. Advantageously, the “conductive parts” 208-03 of the capillaries 208 may be completely metallic. The flow of fluid [symbol] , comprising reactive species, follows the flow in capillaries 208 connected in series with capillary 108, based on a spacing δ₁₋₂ (zero spacing in the example shown in FIG. 8). In addition, the inner surface of capillary 208 of part 208-04 may be made of a dielectric material, allowing plasma columns 202 to be generated at these “dielectric parts” 208-04 of the capillaries 208. Note that the plasma in plasma column 102 is conductive and may be able to apply a voltage to the conductive parts 208-03 attached to the capillary 108. In particular, this applied voltage allows plasma regeneration in plasma columns 202 at the other end of the conductive parts 208-03 (that is, at the dielectric parts 208-04), as well as the transport of reactive species having “long life spans” through these conductive parts 208-03.

In some embodiments, the conductive part 208-03 and the dielectric part 208-04 of a capillary 208 may have equal or different diameters respectively noted [symbol] _{conducteur} and [symbol] _{dielectrique}. A variation in diameters [symbol] _{conducteur} and [symbol] _{dielectrique}, such that for example [symbol] _{conducteur}> [symbol] _{dielectrique} or [symbol] _{conducteur}< [symbol] _{dielectrique}, can induce a slowing or an acceleration of the flow of fluid [symbol] , in capillary 208 to respectively slow down or accelerate the residence time of reactive species in a dielectric part 208-04. Equivalently, the conductive part 208-03 and the dielectric part 208-04 of a capillary 208 may have equal or different lengths.

In some embodiments, other similar capillaries 208-i may be joined to the capillaries 208 already present. The capillaries 208 already present then act as a transfer device 100 for these other capillaries 208-i. A complex device may be created using a single plasma jet production device, and one or more capillaries 208. Each capillary then comprises parts formed from one or more dielectric materials and parts formed from one or more conductive materials. Such a complex device may generate a multitude of oblong-shaped plasmas in the dielectric parts of the capillaries. This multitude of plasmas then forms a so-called “intermittent plasma” having an equivalent length [symbol] . Advantageously, such a configuration comprising other capillaries 208-i allows the target material [symbol] to be treated over a very long length [symbol] while reducing energy consumption compared with a device forming a “continuous” plasma having a long length [symbol] = [symbol] .

In addition, this multitude of plasmas can have a defined geometry depending on the complexity of the arrangement of the different capillaries. For example, at least two capillaries may be connected to each other at one point, at any connection angle, in particular between 0° and 180°. In addition, the plasma columns generated in such a device may be of the same or different nature based on the geometries applied and the fluids contained and/or supplied in these different parts. Advantageously, such a configuration (not shown in the figures) comprising one or more complex connection geometries of three or more capillaries 208-i, at any connection angle (for example 90°), allows the formation of multiple intermittent plasmas from a single transfer device 100 similar to the plasma generator device described in connection with FIGS. 2 and 3.

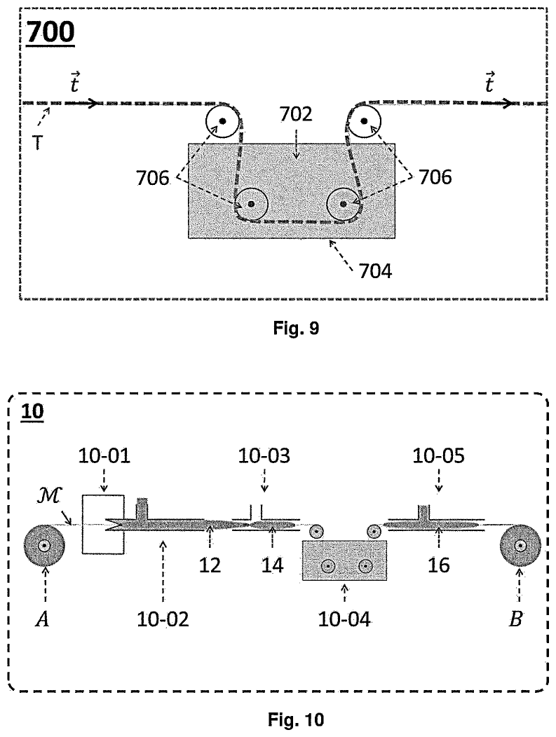

FIG. 9 shows a device for liquid treatment of materials 700 containing a solution in the liquid state 702.

Solution 702 can be any chemical solution already used for the treatment of materials. In particular, solution 702 may contain one or more plasma-treated liquids or gels suitable for the desired treatment. For example, the solution may be a ‘Plasma Activated Water’ (PAW), ‘Plasma Activated Liquid’ (PAL), ‘Plasma Activated Solution’ (PAS), ‘Plasma Activated Medium’ (PAM), or ‘Plasma Activated Gel’ (PAG).

This device for treating materials in the presence of liquid or gel 700 may be, for example, a tank for surface treatment, deposition or modification by immersion of the target material [symbol] in solution 702.

In some embodiments, such a device 700 may be inserted into the system for surface treatment of materials 10 and arranged in series relative to the transfer device 100 and to the plasma generator device 200. This arrangement can take place in various configurations, at any point in the system 10 treatment line along path T of the target material [symbol] .

A first arrangement configuration of device 700 can be defined by positioning the device 700 upstream of the plasma generator device 200. This configuration allows liquid and/or gel deposition on the surface of the target material [symbol] then subsequent treatment for applications to modify the surface of materials with plasma. For example, in the field of optical fiber functionalization, such a configuration allows a protective sheath to be deposited.

A second arrangement configuration of device 700 can be defined by positioning the device 700 downstream of the plasma generator device 200. This configuration allows molecules to be attached to the surface of the target material [symbol] following a previous plasma treatment. In fact, it should be noted that surface treatments of materials by plasma interaction may be treatments that evolve over time defined, for example, according to a time interval τ, depending on the target material [symbol] and the surface properties treated. In order to attach certain plasma treatments, the target material [symbol] may undergo a liquid treatment of materials 700 in this time interval τ. Thus, such a configuration of devices allows an optimum arrangement of plasma treatments using liquid-state solution 702.

FIG. 10 shows a system for surface treatment of materials 10 according to various embodiments, comprising a target material [symbol] passing through constituent components 10-01, 10-02, 10-03, 10-04 and 10-05, between starting point A and end point B.

The target material [symbol] may be for example a material able to be wound on the one hand into a starting coil at point A and on the other hand into an end coil at point B, such as for example a fiber, a wire, a tube or a capillary. Each of these two coils is able to be unwound and wound, so as to allow the target material [symbol] to travel along path T, at a defined speed [symbol] based on the surface treatment to be applied to the target material [symbol] by plasma interaction.

In embodiments, the system for surface treatment of materials 10 (and therefore the two coils starting at point A and ending at point B) is configured so that the target material [symbol] passes through the constituent components 10-01, 10-02, 10-03, 10-04 and 10-05 at least once. For example and without limitation, the route of the target material [symbol] may be a round trip such that the target material [symbol] first passes through constituent components 10-01, 10-02, 10-03, 10-04 and 10-05, then through constituent components 10-05, 10-04, 10-03, 10-02 and 10-01 a second time.

When the target material [symbol] passes through the plasma generator device 200, the interaction with the generated cold plasma can take place either statically or on the fly. A static interaction is defined by the generation of the plasma column 200 when the target material [symbol] is stationary in capillary 208: the velocity [symbol] of the target material [symbol] is then zero ( [symbol] =0 m/s). Similarly, an on-the-fly interaction is defined by the generation of the plasma column 200 when the target material [symbol] is in motion: the velocity [symbol] of the target material [symbol] can then lie between a minimum value [symbol] ₘᵢₙ and a maximum value [symbol] ₘₐₓ.

In other embodiments, the target material [symbol] can be an object, with a large aspect ratio comprising a small object length relative to the size of path T. The target material [symbol] can move on a conveyor belt from a starting point A to an end point B, at a velocity [symbol] defined based on the surface treatment to be applied.

The velocity [symbol] of the target material [symbol] along path T can be limited by a maximum value [symbol] ₘₐₓ defined by the maximum movement limit of the target material [symbol] . In particular, such a maximum velocity [symbol] ₘₐₓ can be determined from a minimum residence time. This minimum residence time is defined by the minimum plasma interaction time with the target material [symbol] to obtain the surface treatment to be applied.

Similarly, the velocity [symbol] of the target material [symbol] along path T can be limited by a minimum value [symbol] ₘᵢₙ defined by the minimum movement limit of the target material [symbol] in the case of an on-the-fly interaction. In particular, such a minimum velocity [symbol] ₘᵢₙ can be determined from a maximum residence time of the target material [symbol] in a generated plasma column. This maximum residence time is defined by the maximum plasma interaction time so as not to damage the target material [symbol] or produce any other unwanted surface treatment.

Advantageously, the system may comprise a plurality of devices 200 generating a plurality of plasma columns 202 arranged in series, with or without transfer devices 100. Such an implementation makes it possible, for example, to perform multiple surface treatments or even to reduce the so-called “local” residence time of the target material [symbol] in a specific plasma column, while guaranteeing a so-called “overall” residence time sufficient to induce the surface treatment to be applied. For example, for natural fibers with very low local residence times, such an implementation allows cooling of the target material [symbol] between two plasma interactions. Alternatively, such an implementation allows plasma heating of the target material M allowing, for example, expansion of the material followed by subsequent surface treatment, thus avoiding the known problems of treated materials undergoing stretching during application as a result of loss of functionalization.

In some embodiments, the velocity [symbol] of the target material [symbol] may vary over time, during the movement of the target material [symbol] in system 10. For example, if the initial properties of the target material [symbol] evolve during the unwinding of the starting coil and/or if the properties to be modified need to evolve during treatment.

Advantageously, the various constituent components 10-01, 10-02, 10-03, 10-04 and 10-05 may be any devices for treating materials or surface of materials. For example, and without limitation, a constituent component may be a device as described above, that is, T-shaped device, an enclosure, or a device for liquid treatment of materials. In particular, the constituent components may be interchangeable to easily adapt the surface treatment of the target material [symbol] according to the desired functionality, depending on the application of the invention.

In the embodiment shown in FIG. 10, component 10-01 is an enclosure comprising a fluid noted [symbol] , similar to the enclosure shown in FIGS. 5, 6 and 7. Components 10-02, 10-03 and 10-05 are also plasma generator devices respectively comprising the fluids, noted [symbol] , [symbol] and [symbol] , similar to the plasma generators shown in FIGS. 2, 3 and 4. Component 10-04 [symbol] is a device for treating materials in the presence of liquid or gel 700, similar to the device for liquid treatment shown in FIG. 9.

Component 10-01 is thus a transfer device 100 with respect to component 10-02, and fluid [symbol] is injected into component 10-02 to create the first plasma column 12 through which the target material [symbol] passes. Similarly, component 10-02 may be a transfer device 100 relative to component 10-03 (depending on the spacing between components 10-02 and 10-03), and fluid [symbol] (or resulting from the mixture of fluids [symbol] and [symbol] ) is injected into component 10-03 to create the second plasma column 14 through which the target material [symbol] passes. Component 10-03 may be a transfer device 100 relative to component 10-05 (depending on the structure of component 10-04 and the spacing between components 10-03 and 10-05), and fluid [symbol] (or resulting from the mixture of fluids [symbol] and [symbol] is injected into component 10-05 to create the third plasma column 16, through which the target material [symbol] passes.

The embodiments of the invention thus allow the generation of multiple, homogeneous atmospheric plasmas over long lengths. These cold plasmas are generated using mixtures that are generally impossible to obtain using other plasma treatment techniques known to the skilled person. Such mixtures comprise, for example, high percentages of nitrogen or oxygen in noble gases. These plasmas are particularly suitable for consecutive, homogeneous plasma treatments of materials with very high aspect ratios.

The various types of device according to the embodiments allow plasmas of different compositions to be generated and combined very easily, one after the other. In addition, the system makes it very easy to inject aerosols, microdroplets, specific vapors or nanomaterials outside plasma generator devices, and to combine these plasma treatments with liquid treatments (or aerosols, or microdroplets). The treatment system according to the embodiments of the invention allows optimum treatment of a material from point A to point B, in a single pass along path T.

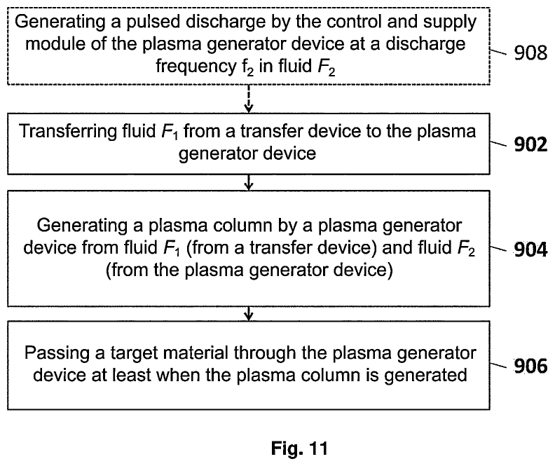

FIG. 11 is a flowchart describing the method of manufacturing an object using a system for surface treatment of materials 10, according to embodiments of the invention.

In step 902, fluid [symbol] is transferred from the transfer device 100 to the plasma generator device 200.

In step 904, the column 202 of cold plasma at atmospheric pressure is generated by the plasma generator device 200 from fluid [symbol] and fluid [symbol] .

In step 906, the target material [symbol] passes through the plasma generator device 200, along path T, at least while the plasma column 202 is being generated. In step 904 or step 902, the target material [symbol] may additionally pass through the transfer device 100 based on the defined path T.

The method may further comprise a step 908 consisting in applying pulsed discharges by the module 204 (and/or the module 104 according to the embodiments) in fluid [symbol] (and/or in fluid [symbol] ), discontinuously at a discharge frequency f₂ (and/or discharge frequency f₁) comprised for example between 10 Hz and 50 kHz.

The skilled person will understand that steps 902, 904, 906 and 908 can be carried out simultaneously and/or in a defined order based on the target material [symbol] and surface properties to be applied.

In some embodiments, several systems for surface treatment of materials 10 can be arranged, in parallel, to form a complete object manufacturing system (not shown in the figures). This complete system may for example comprise n systems configured to treat the surface of n target materials [symbol] . The complete system may further comprise a unit for combining n target materials [symbol] exiting the n surface treatment systems.

The n target materials [symbol] may notably be different or identical materials, and/or require different or identical surface treatments. The n surface treatment systems may comprise the same or different constituent components. The constituent components may be arranged identically or interchanged, depending on the treatments to be applied in the systems.

The object manufacturing method may thus comprise an additional step of combining the n target materials [symbol] after their surface treatment by the n systems.

The combination of n target materials [symbol] may be, for example, a weave of a set of fibers or wires, tubes or capillaries. The combination unit is then a weaving unit.

Such a complete system is ideally suited to multi-fiber weaving or to the manufacture of materials with splices. In particular, this complete system has the advantage of not presenting any shading problems encountered in the surface treatment of assemblies of parts, fibers or wires already combined or woven prior to treatment.

In embodiments, a surface treatment system 10 may comprise k target materials [symbol] able to travel q different paths T within the system 10. The number k of target materials [symbol] may be less than, greater than or equal to the number q of different paths T within the system 10. In this case, the system 10 may further comprise a unit for combining k target materials [symbol] n exiting the surface treatment system, as described above. These embodiments, with k target materials [symbol] able to travel q different paths T, can be combined with the embodiments relating to the complete object manufacturing system comprising several systems for surface treatment of materials 10 for manufacturing woven or combined objects.

The invention is not limited to the embodiments described above by way of non-limiting example. It encompasses all the alternatives that may be envisaged by the skilled person. In particular, the skilled person will understand that the invention is not limited to the transfer devices 100 and to the plasma generator devices 200 described by way of non-limiting example.

1-10. (canceled)

11. A system for surface treatment of materials, comprising a target material ( [symbol] ), at least one transfer device, at least one plasma generator device, characterized in that said transfer device comprises a fluid [symbol] to be transferred to said plasma generator device, said plasma generator device comprising a fluid [symbol] and being configured to generate a column of cold plasma, said target material ( [symbol] ) being able to travel a path (T) at ambient pressure between a starting point (A) and an end point (B), said path passing through at least said plasma generator device and said plasma column, said path (T) being defined in a given reference frame along a unit vector of movement \vec{t}, said fluid [symbol] being transferred from said transfer device to said plasma generator device, and in that said plasma generator device comprises a device for producing a plasma jet obtained from said fluid [symbol] , said plasma column being generated from said fluid [symbol] , and from said plasma jet, and the plasma generator device further comprising a capillary (208) for generating said plasma column arranged so that said plasma column has an oblong geometric shape defined by a length [symbol] , a width [symbol] and an aspect ratio
$$\frac{ℒ}{ℓ} \geq 1 ,$$
said length [symbol] being defined according to a longitudinal axis colinear with the vector of movement \vec{t} and said width [symbol] being defined according to a transverse axis perpendicular to the vector of movement \vec{t}.

12. The system for surface treatment of materials, according to claim 11, wherein the target material ( [symbol] ) additionally passes through at least part of the transfer device.

13. The system for surface treatment of materials, according to claim 11, wherein said capillary comprises an inlet port configured to receive the target material ( [symbol] ) at the inlet of the capillary and an outlet port configured to deliver the target material ( [symbol] ) out of the capillary.

14. The system for surface treatment of materials, according to claim 13, wherein the plasma generator device is a T-shaped device, further comprising a control and supply module for fluid [symbol] and a guide for transporting fluid [symbol] , said control and supply module being configured to apply a pulsed discharge in fluid [symbol] , at a discharge frequency f₂, wherein said guide and said capillary each have a shape and dimensions selected based on the target material ( [symbol] ) and the surface treatment to be applied.

15. The system for surface treatment of materials, according to claim 11, wherein the transfer device is a T-shaped device comprising a capillary and is configured to generate a plasma column, said capillary comprising at least one outlet port, said transfer device and said plasma generator device being spaced apart from each other by a distance ε₁₋₂ representing the distance between the inlet port of the plasma generator device and the outlet port of the transfer device, and wherein said plasma column is generated based on said distance ε₁₋₂.

16. The system for surface treatment of materials, according to claim 14, wherein the capillary of the plasma generator device comprises at least one part made of a conductive material and at least one part made of a dielectric material.

17. The system for surface treatment of materials according to claim 14, wherein the target material ( [symbol] ) has a width ϕ and the capillary has a width [symbol] , the transfer device being an enclosure connected to the plasma generator device by a connection ( [symbol] ) at the inlet port of the plasma generator device, said connection ( [symbol] ) having a given shape and an opening of diameter δ such that ϕ<δ≤ [symbol] , and being adapted to the transfer of fluid [symbol] in the capillary, and wherein said plasma column is generated based on the connection ( [symbol] ).

18. The system for surface treatment of materials according to claim 11, wherein the target material ( [symbol] ) is a fiber, a wire or a capillary, wound on the one hand at the starting point (A), in a starting coil, and on the other hand at the end point (B), in an end coil, each coil being able to be unwound and wound so that the target material ( [symbol] ) travels the path (T) at a given speed [symbol] defined based on said surface treatment to be applied.

19. A method for manufacturing an object using at least one system for surface treatment of materials, said treatment system comprising at least one target material ( [symbol] ), at least one transfer device and at least one plasma generator device, said target material ( [symbol] ) traveling a path (T) between a starting point (A) and an end point (B), said path (T) being defined in a given reference frame according to a unit vector of movement \vec{t}, said transfer device comprising a fluid [symbol] , said plasma generator device comprising a fluid [symbol] , the method comprising the steps of:
transferring fluid [symbol] from the transfer device to the plasma generator device,
generating a cold plasma column at surrounding pressure by means of said plasma generator device from said fluid [symbol] and said fluid [symbol] , said plasma column having an oblong geometric shape defined by a length [symbol] , a width [symbol] and an aspect ratio noted
$$\frac{ℒ}{ℓ} \geq 1 ,$$
said length [symbol] being defined according to a longitudinal axis colinear with the vector of movement \vec{t} and said width [symbol] being defined according to a transverse axis perpendicular to the vector of movement \vec{t}, and
passing said target material ( [symbol] ), along the path (T), through said plasma generator device, at least when said plasma column (202) is generated.

20. The method of manufacturing an object, according to claim 19, wherein step further comprises a step of passing the target material ( [symbol] ) through at least part of the transfer device.
